(19) United States
(12) Patent Application Publication
(10) Pub. No.: US 2025/0291231 A1
(43) Pub. Date: Sep. 18, 2025

(54) OPTICAL LOGIC GATE AND A METHOD FOR ITS OPERATION

(71) Applicant: Akhetonics GmbH, Berlin (DE)

(72) Inventors: Michael Kissner, Dreieich (DE); Leonardo Del Bino, Munich (DE)

(21) Appl. No.: 19/061,892

(22) Filed: Feb. 24, 2025

Related U.S. Application Data
(63) Continuation of application No. PCT/IB2023/057414, filed on Jul. 20, 2023.

(30) Foreign Application Priority Data
Aug. 24, 2022 (DE) 10 2022 121 392.7
Jul. 20, 2023 (WO) PCT/IB2023/057414

(51) Int. Cl. G02F 3/00

(52) U.S. Cl. CPC G02F 3/00

(57) ABSTRACT

An optical logic gate is provided which comprises signal providing means for providing a first optical signal and a second optical signal having the same phases. The optical logic gate further comprises phase modulating means and interference means. The optical logic gate also comprises an optically non-linear element configured to interact with a pump signal and with the first and second optical signals shifted with respect to their phases by the phase modulating means and caused to interfere by the interference means and, as a result of this non-linear interaction, to couple out an optical output signal as a logic output signal.

### CROSS-REFERENCE TO RELATED APPLICATIONS

This application is a continuation-by-pass of PCT/IB2023/057414, filed Jul. 20, 2023, entitled, “OPTICAL LOGIC GATE AND METHOD FOR THE OPERATION THEREOF,” which claims priority to German Patent Application No. 10 2022 121 392.7, filed Aug. 24, 2022, the disclosures of which are incorporated herein by reference in their entirety.

### FIELD OF THE INVENTION

The invention relates to an optical logic gate and a method for its operation.

### BACKGROUND

The use of optical logic, for example optical logic gates, in analog or digital processors promises a substantially faster and more efficient performance of arithmetic operations. In order to ensure this, the optical logic used must meet a number of requirements.

Hence, it should be possible to switch with an optical logic gate as fast as possible using low light intensity. Furthermore, optical logic gates should be flexibly cascadable in order to enable scaling of the respective processor. Further criteria relate to the possibility of achieving a fan-out of at least 2 and of restoring the logic level largely loss-free. In addition, effective isolation of input and output signals and avoidance of critical operating points or corresponding process parameters is advantageous.

However, the known prior art meets these criteria only inadequately, is too slow in switching behavior, requires too much energy for efficient use or cannot be scaled or cascaded efficiently.

It is therefore an object of the invention to propose an optical logic gate and a method for its operation with which the disadvantages of the prior art can be overcome and a large number of the requirements mentioned further above can be met.

### SUMMARY

According to the invention, this object is achieved with a logic gate having the features of the independent claims. Advantageous configurations and developments of the invention can be realized with features designated in dependent claims.

The optical logic gate according to the invention comprises signal providing means for providing a first optical signal based on a first logic input signal and a second optical signal based on a second logic input signal. The respective phases of the first and second optical signals are the same or identical (modulo 21).

The optical logic gate further comprises phase modulating means for shifting the phase of the first optical signal with respect to the phase of the second optical signal by a predetermined phase difference.

The optical logic gate further comprises interference means configured to cause the first and second optical signals shifted with respect to their phases by the phase modulating means to interfere with each other.

The optical logic gate also comprises an optically non-linear element configured to interact with a pump signal and with the first and second optical signals shifted with respect to their phases by the phase modulating means and caused to interfere by the interference means and, as a result of this non-linear interaction, to couple out an optical output signal as a logic output signal.

Here and in the following, the first and second optical signals shifted with respect to their phases by the phase modulating means and caused to interfere by the interference means refer to the superposition signal which is obtained when the first optical signal is caused to interfere with the second optical signal by the interference means after shifting or fixing their relative phase by means of the phase modulating means, the first and second optical signals therefore being superimposed. This superposition signal can then couple into or to the optically non-linear element and thus interact electromagnetically and non-linearly therewith, for example can be transmitted, reflected and/or absorbed completely or at least partially.

The proposed optical logic gate is distinguished by improved cascading and scalability. In particular, the optical logic gate can switch independently of the phase of the first and second logic input signals. Furthermore, the optical logic gate behaves robustly with respect to different noise signals which otherwise can change the phase and/or intensity of an optical signal unpredictably (e.g., randomly).

Since the light supply by means of the (optical) pump signal can be selected independently of the first and second logic input signals, a comparatively high fan-out is achieved, so that the logic gate can be connected efficiently to a plurality of further logic gates. The logic level can thus be restored comparatively efficiently and loss-free.

For example, the intensity of the logic output signal can be greater than the intensity of the first and/or the second logic input signal (even without using an additional optical amplifier). In addition, the relative modulation depth of the optical logic gate is largely independent of the intensity of the first and second logic input signals.

### Mode of Operation and Logic

The optical logic gate can be used in a purely optical analog or digital mode of operation. In the digital mode of operation, it can be used as a modular logic element for performing a large number of logical operations with different logic states.

A logic state can be a first logic state or a second logic state. For example, a first logic state can correspond to a bit with bit value 0 and a second logic state can correspond to a bit with bit value 1 (or vice versa).

Different logic states can be encoded into a signal by means of amplitude or intensity modulation. In the case of amplitude or intensity modulation, a modulated signal, if it is associated with a first logic state, can have a first intensity. The modulated signal can have a second intensity if it is associated with a second logic state.

The second intensity of the modulated signal can be different from the first intensity of the modulated signal. For example, the second intensity of the modulated signal can be greater than the first intensity of the modulated signal.

The modulated signal can be the first or second logic input signal, the first or second optical signal, the superposition signal or the optical output signal or logic output signal. The respective first intensities of different modulated signals can be different from one another. The second intensities of different modulated signals can likewise be different from one another. For example, the first intensity of the first logic input signal can be different from the first intensity of the first optical signal. The second intensity of the first logic input signal can be different from the second intensity of the first optical signal. The same applies analogously to the second logic input signal and the second optical signal.

The signal providing means can be configured such that amplitude or intensity modulation of the first and second logic input signals is transferred to the first and second optical signals. This can be carried out such that the logical state of the first logic input signal corresponds to the logical state of the first optical signal and the logical state of the second logic input signal corresponds to the logical state of the second optical signal.

The predetermined phase difference between the phase of the first optical signal and the phase of the second optical signal can be π or be adjusted accordingly by means of the phase modulating means.

In this case, the interference of the first optical signal and the second optical signal by means of the interfering means can be destructive. The interference can in particular be completely destructive if the intensities of the first and second optical signals are the same, so that they are associated with the same logic states. First optical signal and second optical signal can then almost completely cancel each other out at a predetermined phase difference π in the interfering means and/or optically non-linear element. The superposition or interference signal can then correspond to the first logical state or a zero signal (i.e. for all practical purposes a signal with an intensity equal to zero or smaller than a mean intensity of the noise).

If the intensities of the first and second optical signals are different in size, however, they can be associated with different logical states. For example, exactly one of the two signals can be a zero signal and the respective other one cannot. Then, despite the interference in the interfering means and/or optically non-linear element, the first and second optical signals cannot completely cancel each other out and may interfere only little or not at all with each other. The superposition or interference signal can then correspond to the second logical state or largely correspond to that first or second optical signal before the interference which is not a zero signal at all.

The intensity of the logic output signal can depend on the intensity of the superposition signal and the intensity of the pump signal due to the interaction of the pump signal and the superposition signal with the optically non-linear element.

For example, the intensity of the pump signal can be set or the optically non-linear element can be configured such that the optically non-linear element optically saturates when the superposition signal corresponds to the second logical state or no zero signal, i.e. when the first and second optical signals or the first and second logic input signals have different intensities or correspond to different logical states. In this case, the optical output signal can have a high intensity which can correspond to the second intensity of the optical output signal and can be associated with the second logical state.

The intensity of the pump signal can also be set or the optically non-linear element can also be configured such that the optically non-linear element does not optically saturate when the superposition signal corresponds to the first logical state or a zero signal, i.e. when the first and second optical signals or the first and second logic input signals have the same intensities or correspond to the same logical states. In this case, the optical output signal can have a low intensity which can correspond to the first intensity of the optical output signal or a zero signal and can be associated with the first logical state.

The functionality described further above corresponds to that of a logical XOR function. The optical logic gate can thus be used as an XOR gate.

In particular, the signal providing means together with the optically non-linear element can be configured to associate the intensity of the logic output signal with the respective intensities of the first and second logic input signals such that the logic output signal as a function of the first and second logic input signals is the result of a logical XOR function, wherein the respective logical states of the first and second logic input signals and the logic output signal can be amplitude or intensity modulated.

Preferably, the signal providing means together with the optically non-linear element can be configured such that when the first and second logic input signals have different intensities or are associated with different logical states, the phase of the logic output signal is always the same regardless of which logical states the first and second logic input signals are respectively associated with.

In this case, a purely optical XOR function can be realized in which the phase of the logic output signal is decoupled or is always the same regardless of the phases and/or intensities of the first and second logic input signals or the first and second optical signals. In particular, the phase of the logic output signal can correspond to the phase of the pump signal.

This is achieved in particular in that the superposition signal is first guided together with the pump signal into the optical non-linear element before the logic output signal is generated and coupled out as a result of the non-linear interaction. For example, the material of the optically non-linear element can be selected such that the non-linear interaction is phase-insensitive, for example corresponds to an effective Kerr non-linearity. Preferably, the optically non-linear element has an optically saturable absorber for mediation of the interaction or consists of such an absorber.

The optical output signal can correspond to the portion of the pump signal not absorbed by the optically non-linear element and/or the optically saturable absorber or to the portion of the pump signal transmitted through the optically non-linear element. The phase of the optical output signal can correspond to the phase of the pump signal. The intensity of the optical output signal can be smaller than the intensity of the pump signal as a result of the interaction with the optically non-linear element. The intensity of the optical output signal can also depend on the intensity of the superposition signal and/or the degree of optical saturation of the optically non-linear element.

A signal within the meaning of this invention can be pulsed. The interaction can be carried out simultaneously. In particular, the interaction of the pump signal and the superposition signal with the optically non-linear element can be carried out simultaneously or at least overlapping in time.

A simultaneous interaction of the pump signal and the superposition signal with the optically non-linear element can be carried out such that the pump signal and the superposition signal arrive at the optically non-linear element or couple thereto and interact therewith simultaneously or at least overlapping in time. For example, the pump signal and/or the superposition signal can be absorbed completely or at least partially by an optically saturable absorber in the optically non-linear element.

However, it can also be that the superposition signal first arrives at the optically non-linear element or couples into or to the optically non-linear element and interacts therewith and only thereafter does the pump signal. For example, firstly the superposition signal can be absorbed completely or at least partially by the optically non-linear element or an optically saturable absorber in the optically non-linear element and excite it electromagnetically. During and due to this excitation or absorption, the optically saturable absorber can be saturated. The pump signal can then pass the optically saturable absorber almost completely or at least partially in the optically non-linear element and thus transmit through the optically non-linear element. The pump signal can thus transfer into the optical output signal as a result of a simultaneous interaction of the pump signal and the superposition signal with the optically non-linear element.

The pump signal can pass the optical non-linear element almost completely, partially or not at all depending on the degree of absorption of the superposition signal and/or the excitation or saturation of the optically non-linear element by the superposition signal, in order to realize a logical function of the optical logic gate.

This considerably improves the scalability of the optical logic gate or an optical processor in which the optical logic gate can be implemented or integrated. For example, the phase and/or the intensity of the logic output signal is adjustable or adaptable by selecting the phase and/or intensity of the pump signal. In particular, the phase of the logic output signal can correspond to the phase of the pump signal independently of the respective logic function. The logic output signal can then be used directly as a further input signal in a further logic element or a component of the optical processor.

### Signal Provision

The first optical signal can correspond to the first logic input signal or be identical thereto. The second optical signal can correspond to the second logic input signal or be identical thereto.

However, it can also be that the signal providing means comprises further optical components or elements with which the first logic input signal or the logical state thereof can be transferred to the first optical signal and/or the second logic input signal or the logical state thereof can be transferred to the second optical signal. In this case, the first optical signal can be different from the first logic input signal. The second optical signal can be different from the second logic input signal.

The signal providing means can comprise a first and a second additional optically non-linear element.

The first additional optically non-linear element can be configured to interact with a first additional (optical) pump signal and the first logic input signal and, as a result of this non-linear interaction, to couple out and provide the first optical signal. The interaction of the first additional (optical) pump signal and the first logic input signal with the first additional optically non-linear element can be carried out simultaneously.

The first optical signal can correspond to a portion of the first additional pump signal transmitted through the first additional optically non-linear element. The phase of the first optical signal can correspond to the phase of the first additional pump signal.

The second additional optically non-linear element can be configured to interact with a second additional (optical) pump signal and the second logic input signal and, as a result of this non-linear interaction, to couple out and provide the second optical signal. The interaction of the second additional (optical) pump signal and the second logic input signal with the second additional optically non-linear element can be carried out simultaneously.

The second optical signal can correspond to a portion of the second additional pump signal transmitted through the second additional optically non-linear element. The phase of the second optical signal can correspond to the phase of the second additional pump signal.

Preferably, the first additional pump signal and the first logic input signal propagate in the first additional optically non-linear element or through the first additional optically non-linear element in opposite directions or couple propagating in opposite directions into or to the first additional optically non-linear element.

Preferably, the second additional pump signal and the second logic input signal propagate in the second additional optically non-linear element or through the second additional optically non-linear element in opposite directions or couple propagating in opposite directions into or to the second additional optically non-linear element.

### Optical Non-Linearity

The material of the optically non-linear element, of the first and/or second additional optically non-linear element can be selected such that the respective non-linear interaction is phase-insensitive, preferably corresponds to an effective Kerr non-linearity.

The optically non-linear element, the first and/or second additional optically non-linear element can have an optically saturable absorber or a Kerr medium for mediation of the non-linear interaction or consist of such an absorber.

Preferably, the optically non-linear element, the first and/or second additional optically non-linear element each have a non-linear input/output characteristic in which the intensity of the outgoing or decoupled optical signals or of the electromagnetic emissions describes a non-linear relationship as a function of the sum of the intensities of the simultaneously incoming or coupling optical signals. For example, the non-linear input/output characteristic can describe a sigmoid function or an S-shaped (bistable) curve.

In particular, the input/output characteristic can have a (critical) threshold value for the sum of the intensities of the simultaneously incoming or coupling optical signals, wherein a total intensity of the simultaneously incoming optical signals smaller than the threshold value causes only a low or no (zero signal) intensity of the outgoing (emitted) optical signal, while a total intensity of the simultaneously incoming optical signals greater than the threshold value causes a high intensity of the outgoing optical signal. If the total intensity is greater than the threshold value, the optically non-linear element or its optically saturable absorber can be optically saturated.

Preferably, the intensity of the pump signal is selected or the optically non-linear element is configured such that the optically non-linear element or its optically saturable absorber optically saturates due to the interaction when the first optical signal and the second optical signal are associated with different logical states or have different intensities (and therefore do not completely cancel each other out due to the interference), and does not optically saturate when the first optical signal and the second optical signal are associated with the same logical states or have the same intensities (and therefore completely cancel each other out due to the destructive interference in the case of a relative phase or predetermined phase difference of x).

The optical output signal can correspond to the part of the pump signal propagated or transmitted through the optically non-linear element and/or to the part of the pump signal not absorbed by the optically saturable absorber of the optically non-linear element. In the case of optical saturation, the pump signal can pass the optically non-linear element almost completely or propagate through the optically non-linear element. The optical output signal can then correspond to the second logical state with the second or high intensity.

If the optically non-linear element or its optically saturable absorber is not saturated, the pump signal can at least not pass the optically non-linear element completely or not at all. Instead, it can be absorbed almost completely by its optically saturable absorber. The optical output signal can then correspond to the first logical state with the first or low intensity.

Preferably, the intensity of the first additional pump signal is selected such or the first additional optically non-linear element is configured such that the first additional optically non-linear element or its optically saturable absorber does not optically saturate due to the interaction when the first logic input signal is associated with the first logical state and optically saturates when the first logic input signal is associated with the second logical state.

The first optical signal can correspond to the part of the first additional pump signal propagated or transmitted through the first additional optically non-linear element and/or to the part of the first additional pump signal not absorbed by the optically saturable absorber of the first additional optically non-linear element. In the case of optical saturation, the first additional pump signal can pass the first additional optically non-linear element almost completely or propagate through the first additional optically non-linear element. The first optical signal can then correspond to the second logical state with the second or high intensity.

If the first additional optically non-linear element or its optically saturable absorber is not saturated, the first additional pump signal can at least not pass the first additional optically non-linear element completely or not at all. Instead, it can be absorbed almost completely by its optically saturable absorber. The first optical signal can then correspond to the first logical state with the first or low intensity.

Preferably, the intensity of the second additional pump signal is selected such or the second additional optically non-linear element is configured such that the second additional optically non-linear element or its optically saturable absorber does not optically saturate due to the interaction when the second logic input signal is associated with the first logical state or has a first intensity or corresponds to a zero signal and optically saturates when the second logic input signal is associated with the second logical state.

The second optical signal can correspond to the part of the second additional pump signal propagated or transmitted through the second additional optically non-linear element and/or to the part of the second additional pump signal not absorbed by the optically saturable absorber of the second additional optically non-linear element. In the case of optical saturation, the second additional pump signal can pass the second additional optically non-linear element almost completely or propagate through the second additional optically non-linear element. The second optical signal can then correspond to the second logical state with the second or high intensity.

If the second additional optically non-linear element or its optically saturable absorber is not saturated, the second additional pump signal can at least not pass the second additional optically non-linear element completely or not at all. Instead, it can be absorbed almost completely by its optically saturable absorber. The second optical signal can then correspond to the first logical state with the first or low intensity.

### Graphene

Preferably, the optically non-linear element, the first and/or second additional optically non-linear element has graphene or a graphene layer as optically saturable absorber or medium for mediation of the respective non-linear interaction or is formed therefrom.

For example, the Fermi level of the graphene, e.g. by doping, can be set or selected such that the graphene has a particularly strong or effective detectable absorption. On the one hand, the relaxation time of the saturable absorption of the graphene can be small enough to enable fast switching. On the other hand, the relaxation time of the saturable absorption of the graphene can also be large enough to provide the pump signal, the first additional pump signal and/or the second additional pump signal with a sufficiently long time window, so that it can for example largely independently of a pulse shape of the first and second logic input signals (or of the first and second optical signals) pass the optically non-linear element, the first additional optically non-linear element and/or the second additional optically non-linear element or propagate through it as soon as it is optically saturated. This also makes it possible to effectively restore the phase, pulse shape and/or intensity of the first optical signal, the second optical signal and/or the logic output signal or the logic level and thus additionally contributes to effective scalability.

The relaxation time of the saturable absorption of the graphene can be less than one picosecond. Accordingly, the clock rate of the optical logic gate can be greater than 1 THz.

The use of graphene or a graphene layer also enables an integrated and/or CMOS-based structure of the optical logic gate or of the optically non-linear element, of the first additional optically non-linear element and/or of the second additional optically non-linear element.

In the following, the graphene layer of the first additional optically non-linear element can also be designated as first or first additional graphene layer. In the following, the graphene layer of the second additional optically non-linear element can also be designated as second or second additional graphene layer.

The length(s) of the graphene layer, of the first additional graphene layer and/or of the second additional graphene layer can be different and can each be flexibly set such that the respective threshold value and/or propagation loss of the saturable absorption corresponds to target specifications with regard to the intensity of the signals decoupled from the respective graphene layer, so that different logic functions of the optical logic gate can also be flexibly set. The length(s) can also be selected such that critical points, e.g. bistable phases, are avoided.

The length(s) of the graphene layer, of the first additional graphene layer and/or of the second additional graphene layer can be between 1 and 50 micrometers, preferably between 5 and 15 micrometers. Thus, the total intensity or power of the pump signal supply (total intensity of the pump signal, of the first additional pump signal and of the second additional pump signal) can be less than 100 mW. The intensity of the first and/or second logic input signal can be less than 20 mW.

### Waveguide

The optical logic gate can further comprise at least one waveguide for receiving the pump signal, the optical output signal and/or the first and second optical signals shifted with respect to their phases and caused to interfere by the interference means.

The at least one waveguide can extend through the optically non-linear element and/or couple to the optically non-linear element. The at least one waveguide can also be connected or coupled at one end to a pump or light supply and/or a pump signal coupling element for providing the pump signal and at another end to a logic output for providing the logic output signal.

Preferably, the pump signal can propagate in a first direction and the first and second optical signals shifted with respect to their phases by the phase modulating means and caused to interfere by the interference means can propagate in a second direction opposite to the first direction in the at least one waveguide through the optically non-linear element or couple to the optically non-linear element by propagating in this way.

The at least one waveguide can be configured to receive the pump signal (e.g. coming from the pump supply) propagating in a first direction and to couple it completely or at least partially into/to the optically non-linear element or its optically saturable absorber or its Kerr medium.

The at least one waveguide can further be configured to receive the phase-shifted and interfering/interfered first and second optical signals propagating in a second direction oriented opposite to the first direction and to couple them completely or at least partially into/to the optically non-linear element or its optically saturable absorber or its Kerr medium.

The at least one waveguide can further be configured to receive the optical output signal, wherein the optical output signal is coupling out from the optically non-linear element or its optically saturable absorber or its Kerr medium, and propagates in the first direction and/or to pass it to the logic output.

### Additional Waveguides

### a) Connecting Waveguide

The optical logic gate can further comprise a first and/or second connecting waveguide.

The first connecting waveguide can extend through the first additional optically non-linear element and connect it to the phase modulating means, the interference means, the optically non-linear element and/or the at least one waveguide, wherein the first connecting waveguide can be configured to receive the first additional pump signal and to couple it into or to the first additional optically non-linear element or its optically saturable absorber and/or can be configured to receive the first optical signal and to pass it into or to the phase modulating means, the interference means, the optically non-linear element and/or the at least one waveguide.

The first connecting waveguide can be configured to receive the first additional pump signal and/or the first optical signal propagating in a first direction.

The second connecting waveguide can extend through the second additional optically non-linear element and connect it to the phase modulating means, the interference means, the optically non-linear element and/or the at least one waveguide, wherein the second connecting waveguide can be configured to receive the second additional pump signal and to couple it into or to the second additional optically non-linear element or its optically saturable absorber and/or can be configured to receive the second optical signal and to pass it to or to the phase modulating means, the interference means, the optically non-linear element and/or the at least one waveguide.

The second connecting waveguide can be configured to receive the second additional pump signal and/or the second optical signal propagating in a first direction.

The phase modulating means and/or the interference means can also be arranged on or connected/coupled to the first and/or the second connecting waveguide.

### b) Input Waveguide

The optical logic gate can further comprise a first logic input for providing the first (optical) logic input signal. The first logic input can be connected or coupled via a first input waveguide to the first additional optically non-linear element. The first input waveguide can be configured to receive the first logic input signal (from the first logic input) and to couple the first logic input signal into the first additional optically non-linear element.

The first input waveguide can be coupled to the first connecting waveguide via a first waveguide coupling element. The first waveguide coupling element can be arranged between the first additional optically non-linear element or the phase modulating means or the first heating element and the interference means or the optically non-linear element.

The first waveguide coupling element can be configured such that it propagates the first logic input signal or at least a part of a signal present at the first logic input in the first input waveguide coming from the first logic input into the first connecting waveguide and propagate it further to the first additional non-linear element.

If the first waveguide coupling element only propagates a part of the signal present at the first logic input into the first connecting waveguide, only this part can also be understood as a first logic input signal within the meaning of this application.

The first waveguide coupling element can also be configured such that it propagates the first optical signal or a part of a signal coupled out from the first additional optically non-linear element as a result of the non-linear interaction in the first connecting waveguide coming from the first additional optically non-linear element and/or the phase modulating means and/or the first heating element again into the first connecting waveguide and propagate it further to the interference means and/or the optically non-linear element.

If the first waveguide coupling element only passes a portion of the signal coupled out as a result of the non-linear interaction from the first further optically non-linear element into the first connection waveguide towards the optically non-linear element, only this portion can be understood as a first optical signal within the meaning of this application.

The first input waveguide can extend through the first additional optically non-linear element and/or couple into/to the first additional optically non-linear element or its optically saturable absorber and/or extend there spaced apart from the first connecting waveguide and/or the first additional pump waveguide.

The first logic input signal propagating in a second direction opposite to the first direction, for example in the first input waveguide or the first connection waveguide, can couple into or to the first additional optically non-linear element.

The first input waveguide can additionally also couple into/to the phase modulating means and/or extend through the phase modulating means in order, for example, to shift the phase of the first logic output signal.

The optical logic gate can further comprise a second logic input for providing the second (optical) logic input signal. The second logic input can be connected or coupled via a second input waveguide to the second additional optically non-linear element. The second input waveguide can be configured to receive the second logic input signal (from the second logic input) and to couple the second logic input signal into the second optically non-linear element.

The second input waveguide can be coupled to the second connecting waveguide via a second waveguide coupling element. The second waveguide coupling element can be arranged between the second additional optically non-linear element or the phase modulating means or the second heating element and the interference means or the optically non-linear element.

The second waveguide coupling element can be configured such that it propagates the second logic input signal or at least a portion of a signal present at the second logic input in the second input waveguide coming from the second logic input into the second connecting waveguide and propagate it further to the second additional non-linear element.

If the second waveguide coupling element only propagates a portion of the signal present at the second logic input into the second connecting waveguide, only this portion can also be understood as a second logic input signal within the meaning of this application.

The second waveguide coupling element can also be configured such that it propagates the second optical signal or a part of a signal coupled out from the second additional optically non-linear element as a result of the non-linear interaction in the second connecting waveguide coming from the second additional optically non-linear element and/or the phase modulating means and/or the second heating element again into the second connecting waveguide and propagate it further to the interference means and/or the optically non-linear element.

If the second waveguide coupling element only propagates a portion of the signal coupled out as a result of the non-linear interaction from the second further optically non-linear element into the second connecting waveguide towards the optically non-linear element, only this portion can also be understood as a second optical signal within the meaning of this application.

The second input waveguide can extend through the second additional optically non-linear element and/or couple into/to the second additional optically non-linear element or its optically saturable absorber and/or extend there spaced apart from the second connecting waveguide and/or the second additional pump waveguide.

The second logic input signal propagating in a second direction opposite to the first direction, for example in the second input waveguide or the second connection waveguide, can couple into or to the second additional optically non-linear element.

The second input waveguide can additionally also couple to the phase modulating means and/or extend through the phase modulating means in order, for example, to shift the phase of the second logic output signal;

### c) Output Waveguide

The optical logic gate can further comprise an output waveguide for coupling out and receiving the logic output signal from the optically non-linear element and for propagating or passing the logic output signal to the logic output.

The output waveguide can connect the optically non-linear element directly to the logic output. The output waveguide can also connect or couple the optically non-linear element to the interference means and/or the interference means to the logic output.

The output waveguide can also correspond to or continuously transfer into a part or section of the at least one waveguide.

### d) Pump Supply

The optical logic gate can further comprise a pump waveguide for receiving the pump signal and coupling the pump signal into the optically non-linear element, the pump waveguide can be or continuously transfer into a part or section of the at least one waveguide.

The pump waveguide, the at least one waveguide and/or the output waveguide can also each be a part/section of one and the same waveguide.

The optical logic gate can further comprise a first additional pump waveguide for receiving the first additional pump signal and coupling the first additional pump signal into the first additional optically non-linear element. The first additional pump waveguide can be or continuously transfer into a part or section of the first connecting waveguide (e.g. in/at the first additional optically non-linear element).

The optical logic gate can further comprise a second additional pump waveguide for receiving the second pump signal and coupling the second additional pump signal into the second additional optically non-linear element. The second additional pump waveguide can be or continuously transfer into a part or section of the second connection waveguide (e.g. in/at the second additional optically non-linear element).

The optical logic gate can also comprise a (optical) pump signal supply or light supply for providing the pump signal, the first additional pump signal, the second additional pump signal and/or a total pump signal.

The optical logic gate can also comprise a pump coupling element which is configured to split a total pump signal provided by the pump signal supply into the pump signal, the first additional pump signal and the second additional pump signal and to pass the pump signal into the pump waveguide, the first additional pump signal into the first additional pump waveguide and the second additional pump signal into the second additional pump waveguide. For example, the pump coupling element can be configured as a multi-mode interferometer with one input and three outputs.

The length of the pump waveguide or of the optical path along which the pump signal propagates from the pump coupling element to the optically non-linear element can be longer than the length of the first additional pump waveguide or of the optical path along which the first additional pump signal propagates from the pump coupling element to the first additional optically non-linear element, and can also be longer than the length of the second additional pump waveguide or of the optical path along which the second additional pump signal propagates from the pump coupling element to the second additional optically non-linear element.

A waveguide within the meaning of the present application can be a bidirectional waveguide. Accordingly, a direction or propagation direction in the waveguide can be defined by the sign of the respectively occupied Fourier mode (k-mode).

### CMOS

The optical logic gate can comprise or be integrated in a CMOS-based layer structure.

The graphene layer of the optically non-linear element and the at least one waveguide can be integrated in a CMOS-based layer structure overlapping each other or arranged over each other such that an electromagnetic coupling can be ensured.

The graphene layer can be arranged in or correspond to a first layer of the CMOS-based layer structure. The at least one waveguide can be arranged in a second layer above or below the graphene layer; The first and second layers can also be arranged on each other such that the graphene layer and the at least one waveguide touch each other.

The graphene layer can be configured as a stripe, wherein the longitudinal axes of the graphene stripe and of the at least one waveguide can extend in parallel in the optically non-linear element; The graphene or the graphene stripe can cover the at least one waveguide in the optically non-linear element along the longitudinal axis.

The length of the graphene stripe can be selected such that the threshold value of the optically non-linear element, the propagation loss and/or the intensity of the optical output signal corresponds to a target value. Thus, the threshold value or the point of the saturable absorption and/or the propagation loss can be flexibly adapted to the further construction or design of the optical logic gate. For example, the target value can be selected such that the optical logic gate is not operated at a critical point, for example in a bistable region, of the graphene or of the optically non-linear element.

The features or embodiments mentioned with respect to the configuration of the optically non-linear element can also be transferred or applied analogously to the first and second further optically non-linear elements.

The first further graphene layer and the first connection waveguide and/or the first input waveguide can be integrated in a CMOS-based layer structure overlapping each other or arranged over each other.

The first additional graphene layer of the first additional optically non-linear element can cover the first connecting waveguide and/or the first input waveguide and/or electromagnetically couple thereto.

Preferably, the optically saturable absorber, the Kerr medium and/or the first additional graphene layer of the first additional optically non-linear element covers the first input waveguide, the first additional pump waveguide and/or the first connecting waveguide.

The second further graphene layer and the second connection waveguide and/or the second input waveguide can be integrated in a CMOS-based layer structure overlapping each other or arranged over each other.

The second additional graphene layer of the second additional optically non-linear element can cover the second connecting waveguide and/or the second input waveguide and/or electromagnetically couple thereto.

Preferably, the optically saturable absorber, the Kerr medium and/or the second additional graphene layer of the second additional optically non-linear element covers the second input waveguide, the second additional pump waveguide and/or the second connecting waveguide.

### Interference Means

The interfering means may be a multi-mode interferometer. The multi-mode interferometer as an interference means can be switched or arranged outside and/or between the optically non-linear element and the phase modulating means.

The multi-mode interferometer or interference means can further be configured to cause the first and second optical signals shifted with respect to their relative phase coming from the phase modulating means to interfere and subsequently to forward the correspondingly interfering or interfered or interferingly superimposed signal or superposition signal propagating in the at least one waveguide in the direction of the optically non-linear element.

The interference means can further be configured to propagate the optical output signal in the at least one waveguide and to pass it coming from the optically non-linear element to a logic output.

The interference means can also be a part or region of the optically non-linear element. For example, the interference means can also be configured as a waveguide coupling element.

For example, the at least one waveguide can comprise a first waveguide for receiving the first optical signal, a second waveguide for receiving the second optical signal and a third waveguide for receiving the pump signal and/or for receiving the optical output signal.

The first, second and/or third waveguide can each extend spaced apart from one another through the optically non-linear element or extend next and spaced apart from it. The third waveguide can be arranged in or at the optically non-linear element between the first and the second waveguide.

In this case, the interference means can be formed as a waveguide coupling element by a region in or on the optically non-linear element in which the first and second waveguides each couple to the third waveguide or are arranged close to the third waveguide such that the first and second optical signals shifted with respect to their relative phase interfere or are superimposed with each other in the third waveguide. The superposition signal thus formed can then couple to or into the optically non-linear element or its optically saturable absorber or its Kerr medium.

The graphene layer of the optically non-linear element can completely cover at least the third waveguide in order to ensure simultaneous interaction of the pump signal and the first and second optical signals shifted with respect to their phases and caused to interfere by the interference means with the graphene layer. The graphene layer of the optically non-linear element can additionally also cover the first and second waveguides.

The first waveguide can, for example, correspond to the first connecting waveguide or be or continuously transfer into a part/section thereof.

The second waveguide can, for example, correspond to the second connecting waveguide or be or continuously transfer into a part/section thereof.

The pump waveguide and/or the output waveguide can each correspond to or continuously transfer into a part or section of the third waveguide.

### Phase Modulating Means

The phase modulating means can have at least one heating element which can be suitable for shifting or changing the phase of the first and/or second optical signals such that the relative phase between the first and second optical signals corresponds to the predetermined phase difference. For this purpose, the at least one heating element can be arranged in/at the first and/or second connection waveguide or thermally couple thereto.

The phase modulating means can be arranged or connected between the signal providing means or the first and/or second additional optically non-linear element and the interference means and/or the optically non-linear element. The phase modulating means can also be part of the signal providing means.

In addition, the at least one heating element can also be arranged at the first or second input waveguide or thermally couple thereto.

It can be advantageous if the at least one heating element comprises a first heating element for changing the phase of the first optical signal and a second heating element for changing the phase of the second optical signal. The first heating element can then be arranged at/in the first connecting waveguide or thermally couple thereto. The second heating element can be arranged at/in the second connecting waveguide or thermally couple thereto. Thus, the phase difference between the first and second optical signals can be adjusted particularly precisely, or a corresponding fine tuning can be operated.

Preferably, the phase modulation means, the at least one heating element and/or the first heating element are integrated together with the first additional optically non-linear element, the first connection waveguide and/or the first input waveguide in a CMOS-based layer structure.

The phase modulation means, the at least one heating element and/or the second heating element can also be integrated together with the second additional optically non-linear element, the second connection waveguide and/or the second input waveguide in a CMOS-based layer structure.

Instead of a heating element, at least one electro-optical modulator can also be used as a phase modulating means.

### Method

The invention also relates to a method for operating the optical logic gate described further above. The method comprises the steps of:

Providing a first optical signal based on a first logic input signal and a second optical signal based on a second logic input signal by means of the signal providing means, wherein the respective phases of the first and second optical signals are the same.

Shifting the relative phase of the first and second optical signals by a predetermined phase difference by means of the phase modulating means.

After shifting the relative phase, interfering the first and second optical signals by means of the interfering means.

Interacting a pump signal and the first and second optical signals caused to interfere by the interference means with the optically non-linear element and, as a result of this non-linear interaction, coupling out an optical output signal as a logic output signal from the optically non-linear element.

The method can further comprise, e.g. as an initial step:

Operating the optical logic gate in a digital mode of operation with amplitude or intensity modulation, wherein the predetermined phase difference is π.

Operating in the digital mode of operation can comprise:

Associating a first logic state with a respective first intensity of the first logic input signal, the second logic input signal, and the logic output signal.

Associating a second logic state with a respective second intensity of the first logic input signal, the second logic input signal, and the logic output signal, wherein the second intensity is different from the first intensity.

The associating can be such that the logic output signal as a function of the first and second logic input signals is the result of a logical XOR function.

The logical state of the first logic input signal can be transferred to the first optical signal by means of the signal providing means. The logical state of the second logic input signal can be transferred to the second optical signal by means of the signal providing means.

In particular, when the first and second logic input signals have different intensities or are associated with different logical states, the phase of the logic output signal can always be the same regardless of which logical state the first and second logic input signals are respectively associated with.

The intensity of the pump signal can be selected such that the optically non-linear element or its optically saturable absorber optically saturates upon the simultaneous interaction when the first logic input signal or optical signal and the second logic input signal or optical signal are associated with different logical states and does not optically saturate when the first logic input signal or optical signal and the second logic input signal or optical signal are associated with the same logical states.

Before shifting the relative phase of the first and second optical signals, the method can further comprise:

Interacting a first additional pump signal and the first logic input signal with a first additional optically non-linear element and, as a result of this non-linear interaction, coupling out the first optical signal from the first additional optically non-linear element. The interaction can be carried out simultaneously.

Interacting a second additional pump signal and the second logic input signal with a second additional optically non-linear element and, as a result of this interaction, coupling out the second optical signal from the second additional optically non-linear element. The interaction can be carried out simultaneously.

In the method, the intensity of the pump signal can be selected such that the optically non-linear element or its optically saturable absorber optically saturates upon the interaction when the first logic input signal and the second logic input signal are associated with different logical states and does not optically saturate when the first logic input signal and the second logic input signal are associated with the same logical states.

The intensity of the first additional pump signal and/or the first intensity of the first logic input signal can be selected such that the first additional optically non-linear element or its optically saturable absorber optically saturates upon the interaction when the first logic input signal is associated with the second logical state and does not optically saturate when the first logic input signal is associated with the first logical state.

The intensity of the second additional pump signal and/or the first intensity of the second logic input signal can be selected such that the second additional optically non-linear element or its optically saturable absorber optically saturates upon the interaction when the second logic input signal is associated with the second logical state and does not optically saturate when the second logic input signal is associated with the first logical state.

### Supplementary Remarks

The invention provides an optical logic gate and a method for its operation, with which optical or electro-optical processors can be operated efficiently and scalable or corresponding arithmetic operations can be performed.

In particular, efficient input/output isolation is ensured since no light or no optical signals must flow directly from a logic input into a logic output. The relative modulation depth of the optical logic gate is also largely independent of the (absolute) intensity of the signals provided at the first and second logic inputs.

The optical logic gate according to the invention and the method for its operation can also be used in different optical or electro-optical circuits in the field of network technology and metrology or sensor technology.

Furthermore, the invention is applicable to different optical logic input signals. The logic input signals or the logic output signal can correspond to classical or quasi-classical states of the light or the electromagnetic radiation and even to quantum states, i.e. individual photons or coherent signals with very weak intensity (e.g. corresponding microwave signals).

In addition, it is noted that the term “optical” within the meaning of this invention refers to electromagnetic radiation in general and is not necessarily to be understood as limiting with respect to a frequency range of the electromagnetic radiation used. For example, input or output signals of the optical logic gate or the components thereof, e.g. of the signal providing means and/or of the optically non-linear element, can also be microwave radiation or electromagnetic radiation in the THz range. For example, the optically non-linear element can also be formed with a superconducting circuit which comprises at least one Josephson contact (emitting microwave radiation) or a Tera-Hertz resonator or Tera-Hertz metamaterial. The invention is accordingly applicable and performable in a broad range of the electromagnetic spectrum.

### EXEMPLARY EMBODIMENTS

The optical logic gate and the method for its operation will be explained in more detail below by way of example.

In this case,

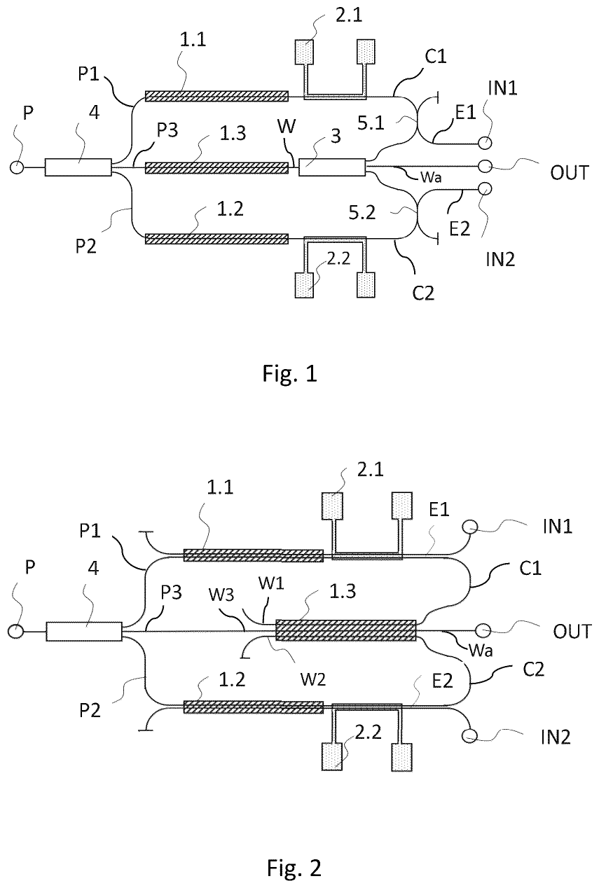

FIG. 1 shows the schematic illustration of an exemplary embodiment of the optical logic gate;

FIG. 2 shows the schematic illustration of a further exemplary embodiment of the optical logic gate;

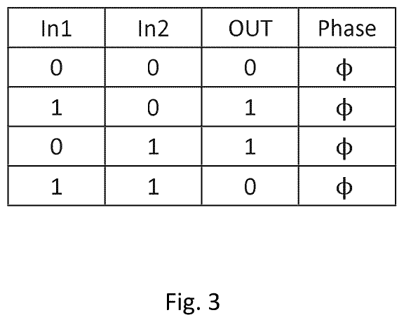

FIG. 3 shows a logic truth table of the optical logic gate;

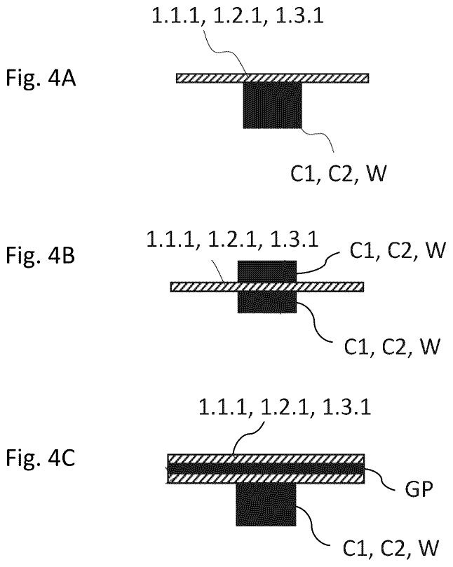

FIGS. 4A, 4B, and 4C each show a schematic illustration of a cross section of a CMOS layer structure with graphene and a waveguide;

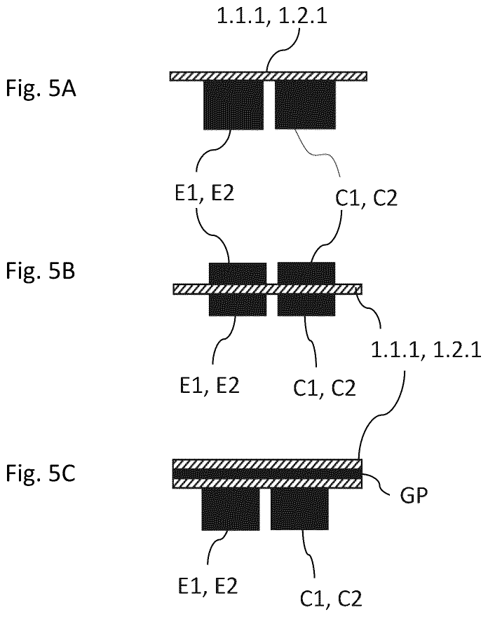

FIGS. 5A, 5B, and 5C each show a schematic illustration of a cross section of a CMOS layer structure with graphene and two waveguides;

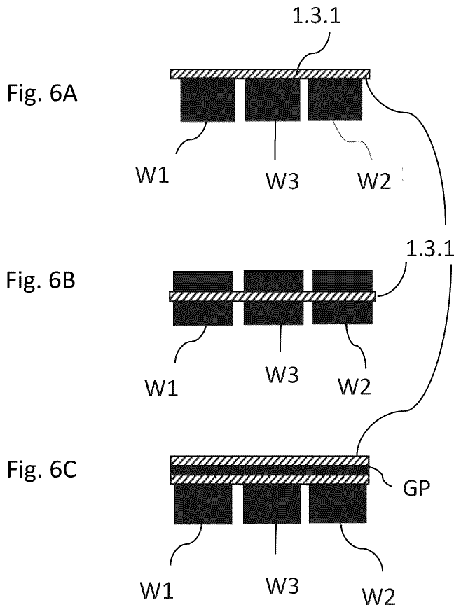

FIGS. 6A, 6B, and 6C each show a schematic illustration of a cross section of a CMOS layer structure with graphene and three waveguides;

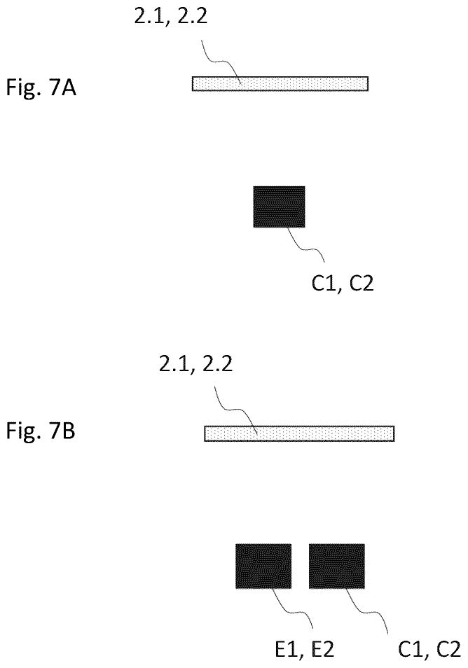

FIG. 7A shows a schematic illustration of a cross section of a CMOS layer structure with the phase modulating means and a waveguide;

FIG. 7B shows a schematic illustration of a cross section of a CMOS layer structure with the phase modulating means and two waveguides;

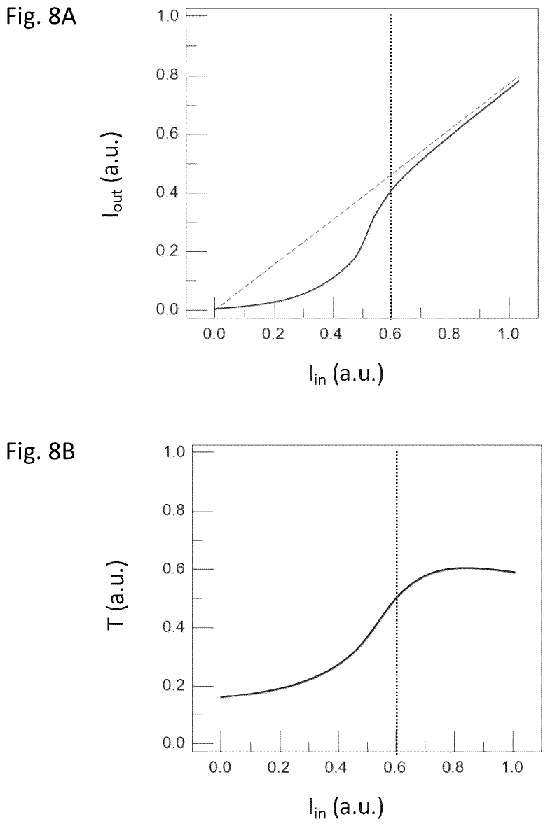

FIG. 8A shows a non-linear input/output characteristic of the optically non-linear element; and

FIG. 8B shows a transmissivity of the optically non-linear element.

The optical logic gate shown in FIG. 1 comprises a signal providing means 1.1, 1.2 for providing a first optical signal based on a first logic input signal and a second optical signal based on a second logic input signal. The respective phases of the first and second optical signals are the same or identical (modulo 2π).

The optical logic gate further comprises phase modulating means 2.1, 2.2 for shifting the phase of the first optical signal with respect to the phase of the second optical signal by a predetermined phase difference.

The optical logic gate further comprises interference means 3 configured to cause the first and second optical signals shifted with respect to their phases by the phase modulating means 2.1, 2.2 to interfere with each other.

The optical logic gate also comprises an optically non-linear element 1.3 configured to interact with a pump signal and with the first and second optical signals shifted with respect to their phases by the phase modulating means 2.1, 2.2 and caused to interfere by the interference means 3 and, as a result of this non-linear interaction, to couple out an optical output signal as a logic output signal.

The signal providing means 1.1, 1.2 comprises a first additional optically non-linear element 1.1 and a second additional optically non-linear element 1.2.

The phase modulating means 2.1, 2.2 comprises a first heating element 2.1 and a second heating element 2.2.

The interference means 3 is configured as a multi-mode interferometer and is coupled between the first and second heating element 2.1, 2.2 on the one hand and the optically non-linear element 1.3 on the other hand.

The first connecting waveguide C1 connects or couples the first additional optically non-linear element 1.1 to the first heating element 2.1 and the interference means 3. The second connecting waveguide C2 connects or couples the second additional optically non-linear element 1.2 to the second heating element 2.2 and the interference means 3.

The first input waveguide E1 connects or couples the first logic input IN1 via the first waveguide coupling element 5.1 to the first connecting waveguide C1. The second input waveguide E2 connects or couples the second logic input IN2 via the second waveguide coupling element 5.2 to the second connecting waveguide C2.

The at least one waveguide W connects or couples the interference means 3 to the optically non-linear element 1.3 and extends through it. In this example, the at least one waveguide W consists of a single waveguide designated as pass-through waveguide W in the following.

The output waveguide Wa connects or couples the interference means 3 to the logic output OUT.

The pump signal supply P is connected or coupled via the pump coupling element 4 to the pump waveguide P3, the first additional pump waveguide P1 and the second additional pump waveguide P2. The pump coupling element 4 is likewise configured as a multi-mode interferometer.

The pump signal supply provides a total pump signal which is split by the pump coupling element 4 into the pump signal, the first additional pump signal and the second additional pump signal. The pump signal is received by the pump waveguide P3 and propagates into the pass-through waveguide W and into the optically non-linear element 1.3 or couples thereto. The first additional pump signal is received by the pump waveguide P1 and propagates into the first additional optically non-linear element 1.1 or couples thereto. The second additional pump signal is received by the second additional pump waveguide P2 and propagates into the second additional optically non-linear element 1.2 or couples thereto.

The first additional pump waveguide P1 continuously transfers into the first connecting waveguide C1. The second pump waveguide continuously transfers into the second connecting waveguide C2.

The first logic input IN1 provides the first logic input signal. This is received by the first input waveguide E1 and propagates via the first waveguide coupling element 5.1 into the first connecting waveguide C1, through the first heating element 2.1 into the first additional optically non-linear element 1.1 or couples thereto.

The second logic input IN2 provides the second logic input signal. This is received by the second input waveguide E2 and propagates via the second waveguide coupling element 5.2 into the second connecting waveguide C2, through the second heating element 2.2 into the second additional optically non-linear element 1.2 or couples thereto.

The first logic input signal and the first additional pump signal thus propagate in the first connection waveguide C1 and the first additional optically non-linear element 1.1 in respectively opposite directions (in respectively positive and negative k-modes). The second logic input signal and the second additional pump signal also propagate in the second connection waveguide C2 and the second additional optically non-linear element 1.2 in opposite directions (in respectively positive and negative k-modes).

The first additional optically non-linear element 1.1 has a first additional graphene layer 1.1.1 as optically saturable absorber. The first additional graphene layer 1.1.1 is configured as a stripe which extends along its longitudinal axis in parallel to and above the first connecting waveguide C1 and covers it. The first additional pump signal and the first logic input signal couple to the first additional graphene layer 1.1.1 by means of the first connecting waveguide C1 in the first additional optically non-linear element 1.1 and interact therewith simultaneously.

As a result of this non-linear interaction, the first additional optically non-linear element 1.1 couples out the first optical signal and also provides it in the first connecting waveguide C1. The first optical signal corresponds to the portion of the first additional pump signal not absorbed by the first additional graphene layer 1.1.1 or to the portion of the first additional pump signal transmitted through the first additional optically non-linear element 1.1. The phase of the first optical signal corresponds to the phase of the first additional pump signal.

The second additional optically non-linear element 1.2 has a second additional graphene layer 1.2.1 as optically saturable absorber. The second additional graphene layer 1.2.1 is configured as a stripe which extends along its longitudinal axis in parallel to the second connecting waveguide C2 and covers it. The second additional pump signal and the second logic input signal couple to the second additional graphene layer 1.2.1 by means of the second connecting waveguide C2 in the second additional optically non-linear element 1.2 and interact therewith simultaneously.

As a result of this non-linear interaction, the second additional optically non-linear element 1.2 couples out the second optical signal and also provides it in the second connecting waveguide C2. The second optical signal corresponds to the portion of the second additional pump signal not absorbed by the second additional graphene layer 1.2.1 or to the portion of the second additional pump signal transmitted through the second additional optically non-linear element 1.2. The phase of the second optical signal corresponds to the phase of the second additional pump signal.

The first optical signal propagates in the first connection waveguide C1 in/to the first heating element 2.1, the second optical signal propagates in/to the second heating element 2.2. The first 2.1 and second 2.2 heating elements are configured to adjust a predetermined phase difference or relative phase between the first and second optical signals. The predetermined phase difference or relative phase is. The first and second optical signals shifted with respect to their relative phases propagate via the first 5.1 and second 5.2 waveguide coupling element into the interference element 3.

The interference element 3 superimposes or interferes the first and second optical signals and directs the corresponding superposition signal into the pass-through waveguide W. There, it propagates further into the optically non-linear element 1.3. The superposition signal or the first and second optical signals shifted with respect to their phases and caused to interfere by the interference means 3 and the pump signal propagate in the pass-through waveguide W and in/at the optically non-linear element 1.3 in opposite directions (in respectively positive and negative k-modes).

The optically non-linear element 1.3 has a graphene layer 1.3.1 as optically saturable absorber. The graphene layer 1.3.1 is configured as a stripe which extends along its longitudinal axis in parallel to the pass-through waveguide W and covers it. The pump signal and the superposition signal couple to the graphene layer 1.3.1 by means of pass-through waveguide W in the optically non-linear element 1.3 and interact therewith simultaneously.

As a result of this non-linear interaction, the graphene layer 1.3.1 or the optically non-linear element 1.3 couples out the optical output signal into the pass-through waveguide W. There, it propagates in the direction of the interference means 3 and is guided by the latter further into the output waveguide Wa and to the logic output OUT.

The optical output signal is substantially identical to the logic output signal (except for propagation losses in the waveguides etc.) and corresponds to the portion of the pump signal not absorbed by the graphene layer 1.3.1 or to the portion of the pump signal transmitted through the optically non-linear element 1.3. The phase of the logic output signal corresponds to the phase of the pump signal.

The waveguides shown in FIG. 1 consist of silicon nitride.

The reference symbols introduced in FIG. 1 are used identically in the figures described below.

The example of an optical logic gate shown in FIG. 2 differs from the example shown in FIG. 1 in that the first input waveguide E1 extends spaced apart from the first connection waveguide 1 through the first additional optically non-linear element 1.1 and the first heating element 2.1. The first additional graphene layer 1.1.1 covers both the first input waveguide E1 and the first connecting waveguide C1 in the first additional optically non-linear element 1.1.

The second input waveguide E2 extends spaced apart from the second connection waveguide C2 through the second additional optically non-linear element 1.2 and the second heating element 2.2. The second additional graphene layer 1.2.1 covers both the second input waveguide E2 and the second connecting waveguide C2 in the second additional optically non-linear element 1.2.

In FIG. 2, the at least one waveguide W has a first waveguide W1, a second waveguide W2 and a third waveguide W3. The first connecting waveguide C1 continuously transfers into the first waveguide W1. The second connecting waveguide C2 continuously transfers into the second waveguide W2. The pump waveguide P3 continuously transfers into the third waveguide W3. The third waveguide W3 continuously transfers into the output waveguide Wa.

The first W1, second W2 and third W3 waveguide extend spaced apart from one another through the optically non-linear element 1.3. The third waveguide W3 is arranged in the optically non-linear element 1.3 between the first W1 and the second W2 waveguide.

The interference means 3 is a part or region of the optically non-linear element 1.3 as a waveguide coupling element.

In this region, the first W1 and second W2 waveguides each couple to the third waveguide W3 or extend close to the third waveguide W3 such that the first and second optical signals shifted with respect to their relative phase interfere or are superimposed with each other in the third waveguide W3.

In this region, the graphene layer 1.3.1 of the optically non-linear element 1.3 also covers the first W1, second W2 and third W3 waveguides in order to enable interaction of the pump signal and the first and second optical signals shifted with respect to their phases and caused to interfere by the interference means 3 with the graphene layer 1.3.1.

The optical logic gate shown in the examples of FIGS. 1 and 2 is operated in a digital mode of operation. First and second logic states are encoded by means of amplitude or intensity modulation.

A first logic state with bit value 0 is associated with the first and second logic input signals and the logic output signal when they each have a first intensity, and a second logic state with bit value 1 is associated with the first and second logic input signals and the logic output signal when they each have a second intensity, wherein the second intensity of a signal is higher than the first intensity of this signal.

The signal providing means 1.1, 1.2 together with the optically non-linear element 1.3 are configured to associate the intensity of the logic output signal at the logic output OUT with the respective intensities of the first and second logic input signals at the first and second logic inputs IN1, IN2 such that the logic output signal as a function of the first and second logic input signals is the result of a logical XOR function.

The intensity of the first additional pump signal and of the first additional graphene layer 1.1.1 are configured such that the first additional graphene layer 1.1.1 or the first additional optically non-linear element 1.1 does not optically saturate when the first logic input signal has the first intensity of the first logic input signal or corresponds to the first logical state (bit value 0). In particular, the total intensity, i.e. the addition of the intensities of the first additional pump signal and of the first logic input signal, is smaller than the threshold value of the first additional graphene layer 1.1.1 when the first logic input signal corresponds to the first logical state. In this case, the intensity of the out-coupled or provided first optical signal is likewise low or even corresponds to a zero signal. The first optical signal then has the first intensity of the first optical signal or is associated with the first logic state (bit value 0).

The intensity of the first additional pump signal and of the first additional graphene layer 1.1.1 are further configured such that the first additional graphene layer 1.1.1 or the first additional optically non-linear element 1.1 optically saturates when the first logic input signal has the second intensity of the first logic input signal or corresponds to the second logical state (bit value 1). In particular, the total intensity, i.e. the addition of the intensities of the first additional pump signal and of the first logic input signal, is greater than the threshold value of the first additional graphene layer 1.1.1 when the first logic input signal corresponds to the second logical state. In this case, the intensity of the out-coupled or provided first optical signal is high and does not correspond to a zero signal. The first optical signal then has the second intensity of the first optical signal or is associated with the second logic state (bit value 1).

The intensity of the second additional pump signal and of the second additional graphene layer 1.2.1 are configured such that the second additional graphene layer 1.2.1 or the second additional optically non-linear element 1.2 does not optically saturate when the second logic input signal has the first intensity of the second logic input signal or corresponds to the first logical state (bit value 0). In particular, the total intensity, i.e. the addition of the intensities of the second additional pump signal and of the second logic input signal, is smaller than the threshold value of the second additional graphene layer 1.2.1 when the second logic input signal corresponds to the first logical state. In this case, the intensity of the out-coupled or provided second optical signal is likewise low or even corresponds to a zero signal. The second optical signal then has the first intensity of the second optical signal or is associated with the first logic state (bit value 0).

The intensity of the second additional pump signal and of the second additional graphene layer 1.2.1 are further configured such that the second additional graphene layer 1.2.1 or the second additional optically non-linear element 1.2 optically saturates when the second logic input signal has the second intensity of the second logic input signal or corresponds to the second logical state (bit value 1). The total intensity, i.e. the addition of the intensities of the second additional pump signal and of the second logic input signal, is greater than the threshold value of the second additional graphene layer 1.2.1 when the second logic input signal corresponds to the second logical state. In this case, the intensity of the out-coupled or provided second optical signal is high and does not correspond to a zero signal. The second optical signal then has the second intensity of the second optical signal or is associated with the second logic state (bit value 1).

The non-linear interactions mediated by the first 1.1.1 and second 1.2.1 additional graphene layer are phase-insensitive. Thus, although the logical states of the first and second logic input signals are respectively transferred to the first and second optical signals by the signal providing means 1.1, 1.2, the phases of the first and second optical signals are identical independently of the phases of the first and second logic input signals. This enables precise and efficient shifting of the relative phase by the first 2.1 and second 2.2 heating elements.

After fixing or shifting the relative phase of the first and second optical signals by the first and second heating elements 2.1, 2.2, the first and second optical signals arrive simultaneously at the interfering means 3. This brings the first and second optical signals into interference or superposition such that the superposition signal corresponds to a zero signal (completely destructive interference) when the first optical signal and the second optical signal are associated with the same logical states. The superposition signal itself is then associated with the first logic state (low intensity or zero signal) (bit value 0).

The superposition signal does not correspond to a zero signal when the first optical signal and the second optical signal are associated with different logical states. In one exemplary embodiment, the signal providing means 1.1, 1.2 is configured such that the first intensity of the first and second optical signals respectively corresponds to a zero signal (first logical state). The superposition signal then corresponds precisely to that first or second optical signal which corresponds to the second logical state with high intensity. The superposition signal itself is then associated with the second logic state (high intensity) (bit value 1).

The superposition signal then couples simultaneously with the pump signal to the optically non-linear element 1.3 or its graphene layer 1.3.1.

the intensity of the pump signal and of the graphene layer 1.3.1 are configured such that the graphene layer 1.3.1 or the optically non-linear element 1.3 does not optically saturate when the superposition signal corresponds to the first logical state (bit value 0); In particular, the total intensity, i.e. the addition of the intensities of the pump signal and of the superposition signal, is smaller than the threshold value of the graphene layer 1.3.1 or of the optically non-linear element 1.3 when the superposition signal corresponds to the first logical state. In this case, the intensity of the out-coupled optical output signal is likewise low or even corresponds to a zero signal. The optical output signal then has the first intensity of the optical output signal or is associated with the first logic state (bit value 0).

The intensity of the pump signal and of the graphene layer 1.3.1 are further configured such that the graphene layer 1.3.1 or the optically non-linear element 1.3 optically saturates when the superposition signal corresponds to the second logical state (bit value 1); The total intensity, i.e. the addition of the intensities of the pump signal and of the superposition signal, is greater than the threshold value of the graphene layer 1.3.1 or of the optically non-linear element 1.3 when the superposition signal corresponds to the second logical state. In this case, the intensity of the out-coupled optical output signal is high and does not correspond to a zero signal. The optical output signal then has the second intensity of the optical output signal or is associated with the second logic state (bit value 1).

FIG. 3 shows a logic truth table which corresponds to the logical XOR function described further above.

The first column corresponds to the logic state or bit value of the first logic input signal at the first logic input IN1. The second column corresponds to the logic state or bit value of the second logic input signal at the second logic input IN2. The third column corresponds to the logic state or bit value of the optical output signal or logic output signal at the logic output OUT. The fourth column corresponds to the phase of the logic output signal.

The phase q of the logic output signal is always the same regardless of which logical state the first and second logic input signals are respectively associated with. The phase φ corresponds to the phase of the pump signal.

This considerably improves the modularity and scalability of the optical logic gate.

FIGS. 4A-4C, 5A-5C and 6A-6B show schematic illustrations of cross sections through the optical logic gate with a CMOS layer structure in which a graphene layer (hatched area) covers one, two or three waveguides (black area) in each case.

The graphene layer 1.3.1 as part of the optically non-linear element 1.3, the first additional graphene layer 1.1.1 as part of the first additional optically non-linear element 1.1 and the second additional graphene layer 1.2.1 as part of the second additional optically non-linear element 1.2 are each configured as stripes. The cross sections shown correspond to normal planes with respect to the layer plane of the graphene or the longitudinal axis of the graphene stripes and waveguides shown.

FIGS. 4A, 4B and 4C correspond to the exemplary embodiment shown in FIG. 1.

In FIGS. 4A, 4B and 4C, the graphene layer 1.3.1 is arranged on or connected to the at least one waveguide or through waveguide W. Analogously thereto, the first further graphene layer 1.1.1 is arranged on or connected to the first connection waveguide C1. The second additional graphene layer 1.2.1 is arranged on or connected to the second connection waveguide C2.

In FIG. 4A, the graphene layer 1.3.1 is arranged above the at least one waveguide or through waveguide W, the first additional graphene layer 1.1.1 is arranged above the first connecting waveguide C1 and the second additional graphene layer 1.2.1 is arranged above the second connecting waveguide C2.

In FIG. 4B, the at least one waveguide or through waveguide W, the first connecting waveguide C1 and the second connecting waveguide C2 each consist of an upper partial layer and a lower partial layer. The respective graphene layer is arranged between the upper and lower partial layers and connected to the first and second partial layers.

In FIG. 4C, the graphene layer 1.3.1, the first additional graphene layer 1.1.1 and the second additional graphene layer 1.2.1 each consist of at least two partial layers or layers of the graphene with a corresponding passivation GP between two partial layers or layers. The passivation GP can be formed with silicon nitride or silicon oxide or consist thereof.

FIGS. 5A, 5B and 5C each correspond to a schematic illustration of a cross section of a CMOS layer structure with graphene analogously to FIGS. 4A, 4B and 4C, but with two waveguides each according to the exemplary embodiment shown in FIG. 2. In this case, the first additional graphene layer 1.1.1 is arranged directly on the first connection waveguide C1 and the first input waveguide E1. The second additional graphene layer 1.2.1 is arranged directly on the second connection waveguide C2 and the second input waveguide E2.

FIGS. 6A, 6B and 6C each correspond to a schematic illustration of a cross section of a CMOS layer structure with graphene analogously to FIGS. 4A, 4B and 4C, but with three waveguides each according to the exemplary embodiment shown in FIG. 2. In this case, the graphene layer 1.3.1 of the optically non-linear element 1.3 is arranged directly on the first waveguide W1, the second waveguide W2 and the third waveguide W3.

FIGS. 7A and 7B show the schematic illustration of cross sections through the phase modulating means 2.1, 2.2.

The first 2.1 and second 2.2 heating elements each have a metal layer (dotted areas) which is electrically contacted and can thereby be heated. The electrical resistance of the respective metal layer leads to heating and changing the refractive index in the respective waveguides located thereunder when an electrical power supply is applied.

The cross sections shown in FIGS. 7A-7B correspond to normal planes with respect to the layer planes of the metal layers and the longitudinal axes of the waveguides shown.

FIG. 7A shows a cross section of the CMOS-based layer structure of the phase modulating means 2.1, 2.2 according to the exemplary embodiment shown in FIG. 1.

The first heating element 2.1 is arranged with its metal layer above the first connecting waveguide C1 and spaced apart from it. The first heating element 2.1 is integrated with the first connection waveguide C1 in a CMOS layer structure.

The second heating element 2.2 is arranged with its metal layer above the second connecting waveguide C2 and spaced apart from it. The second heating element 2.2 is integrated with the second connection waveguide C2 in a CMOS layer structure.

FIG. 7B shows a cross section of the CMOS-based layer structure of the phase modulating means 2.1, 2.2 according to the exemplary embodiment shown in FIG. 2.

The first heating element 2.1 is arranged with its metal layer above the first connection waveguide C1 and the first input waveguide E1 and spaced apart from it. The first heating element 2.1 is integrated with the first connection waveguide C1 and the first input waveguide E1 in a CMOS layer structure.

The second heating element 2.2 is arranged with its metal layer above the second connection waveguide C2 and the second input waveguide E2 and spaced apart from it. The second heating element 2.2 is integrated with the second connection waveguide C2 and the second input waveguide E2 in a CMOS layer structure.

FIGS. 8A and 8B show a non-linear input/output characteristic and a transmissivity of the optically non-linear element 1.3.

FIG. 8A shows the intensity of the optical output signal Iₒᵤₜ as a function of the total intensity Iᵢₙ of the simultaneously coupled or interacting input signals (solid line). The total intensity Iᵢₙ corresponds to the sum of the intensity of the pump signal I_{P} and the intensity of the superposition signal. The vertically dotted line corresponds to the threshold value of the saturable absorption of the optically non-linear element 1.3 or of the graphene layer 1.3.1.

If the total intensity Iᵢₙ of the simultaneously coupled or interacting input signals is smaller than the threshold value, the intensity of the optical output signal Iₒᵤₜ is very low (e.g. zero signal). The optical output signal then has the first intensity of the optical output signal or corresponds to the first logic state. This is the case when the first and second logic input signals correspond to different logical states.

If the total intensity Iᵢₙ of the simultaneously coupled or interacting input signals is greater than the threshold value, the intensity of the optical output signal Iₒᵤₜ is high (no zero signal). The optical output signal then has the second intensity of the optical output signal or corresponds to the second logic state. This is the case when the first and second logic input signals correspond to the same logical states.

FIG. 8B shows the transmissivity T of the optically non-linear element 1.3 or the portion of the pump signal not absorbed by the graphene layer 1.3.1 and transmitted through the optically non-linear element 1.3 as a function of the total intensity Iᵢₙ.

The transmissivity T results from the comparison of the intensity of the pump signal Iₚ with the intensity of the optical output signal Iₒᵤₜ, wherein Iₒᵤₜ=T Iₚ. The transmissivity T is in an exponential relationship with the length x of the graphene layer 1.3.1, wherein T=e^{-αx} with an intense propagation loss α=α(Iᵢₙ) (per micrometer). The transmissivity T describes a sigmoid function with the threshold value of the optical saturation as an inflection point.

Below the threshold value, the transmissivity T is low and the pump signal is almost completely absorbed by the graphene layer 1.3.1 in the optically non-linear element 1.3. The logic output signal has a correspondingly low intensity which corresponds to the first intensity of the optical output signal.

Above the threshold value, the transmissivity T has a plateau as a signature of the optical saturation of the optically non-linear element 1.3 or of the graphene layer 1.3.1. The pump signal can transmit through the optically non-linear element 1.3 or pass the graphene layer 1.3.1 without being completely absorbed. The logic output signal has a correspondingly high intensity which corresponds to the second intensity of the optical output signal.

Individual or a plurality of features of the exemplary embodiments shown in FIGS. 1 to 8B can also be combined with one another.

1. An optical logic gate comprising:
signal providing means for providing a first optical signal based on a first logic input signal and a second optical signal based on a second logic input signal, wherein the respective phases of the first and second optical signals are the same;
phase modulating means for shifting the phase of the first optical signal with respect to the phase of the second optical signal by a predetermined phase difference;
interference means configured to cause the first and second optical signals shifted with respect to their phases by the phase modulating means to interfere with each other; and
an optically non-linear element configured to interact with a pump signal and with the first and second optical signals shifted with respect to their phases by the phase modulating means and caused to interfere by the interference means and, as a result of this non-linear interaction, to couple out an optical output signal as a logic output signal.

2. The optical logic gate according to claim 1, wherein the predetermined phase difference is π.

3. The optical logic gate according to claim 1, wherein the optically non-linear element is configured such that the non-linear interaction is phase-insensitive.

4. The optical logic gate according to claim 1, wherein the optical logic gate is an XOR gate.

5. The optical logic gate according to claim 4, wherein the signal providing means together with the optically non-linear element are configured to associate the intensity of the logic output signal with the respective intensities of the first and second logic input signals such that the logic output signal as a function of the first and second logic input signals is the result of a logical XOR function, wherein the respective logical states of the first and second logic input signals and the logic output signal are intensity modulated.

6. The optical logic gate according to claim 5, wherein the signal providing means is configured such that the logical state of the first logic input signal corresponds to the logical state of the first optical signal and the logical state of the second logic input signal corresponds to the logical state of the second optical signal.

7. The optical logic gate according to claim 5, wherein the signal providing means together with the optically non-linear element are configured such that when the first and second logic input signals have different intensities or correspond to different logical states, the phase of the logic output signal is always the same regardless of which logical state the first and second logic input signals are respectively associated with.

8. The optical logic gate according to claim 1, wherein the optical output signal corresponds to the portion of the pump signal transmitted through the optically non-linear element.

9. The optical logic gate according to claim 1, wherein the phase of the optical output signal corresponds to the phase of the pump signal.

10. An optical logic gate comprising:
signal providing means for providing a first optical signal based on a first logic input signal and a second optical signal based on a second logic input signal;
phase modulating means for shifting the phase of the first optical signal with respect to the phase of the second optical signal by a predetermined phase difference;
interference means configured to cause the first and second optical signals shifted with respect to their phases by the phase modulating means to interfere with each other; and
an optically non-linear element configured to interact with a pump signal and with the first and second optical signals shifted with respect to their phases by the phase modulating means and caused to interfere by the interference means and, as a result of this non-linear interaction, to couple out an optical output signal as a logic output signal,
wherein the optically non-linear element comprises an optically saturable absorber for mediating the non-linear interaction in the optically non-linear element.

11. The optical logic gate according to claim 10, wherein the optical output signal corresponds to a portion of the pump signal not absorbed by the optically saturable absorber and transmitted through the non-linear element.

12. The optical logic gate according to claim 10, wherein the optically non-linear element comprises a graphene layer as an optically saturable absorber for mediating the non-linear interaction in the optically non-linear element.

13. The optical logic gate according to claim 10, further comprising at least one waveguide passing through the optically non-linear element or coupling to the optically non-linear element, wherein the at least one waveguide is configured to:
couple the pump signal propagating in a first direction into or to the optically non-linear element;
receive the optical output signal propagating in the first direction from the optically non-linear element; and
receive the first and second optical signals propagating in a second direction opposite to the first direction and coupling them into or to the optically non-linear element, wherein the first and second optical signals are shifted with respect to their phases by the phase modulating means and caused to interfere by the interference means.

14. The optical logic gate according to claim 12, wherein the graphene layer and the at least one waveguide are integrated in a CMOS-based layer structure and arranged over each other such that an electromagnetic coupling is ensured between the graphene layer and the at least one waveguide.

15. The optical logic gate according to claim 10, wherein the respective phases of the first and second optical signals are the same.

16. An optical logic gate comprising:
signal providing means for providing a first optical signal based on a first logic input signal and a second optical signal based on a second logic input signal;
phase modulating means for shifting the relative phase of the first optical signal with respect to the phase of the second optical signal by a predetermined phase difference;
interference means configured to cause the first and second optical signals shifted with respect to their phases by the phase modulating means to interfere with each other; and
an optically non-linear element configured to interact with a pump signal and with the first and second optical signals shifted with respect to their phases by the phase modulating means and caused to interfere by the interference means and, as a result of this non-linear interaction, to couple out an optical output signal as a logic output signal,
wherein the signal providing means comprise a first and a second additional optically non-linear element, and wherein
the first additional optically non-linear element is configured to interact with a first additional pump signal and the first logic input signal and, as a result of this non-linear interaction, to couple out and provide the first optical signal; and
the second additional optically non-linear element is configured to interact with a second additional pump signal and the second logic input signal and, as a result of this non-linear interaction, to couple out and provide the second optical signal.

17. The optical logic gate according to claim 16, wherein the first optical signal corresponds to a portion of the first additional pump signal transmitted through the first additional optically non-linear element; and
the second optical signal corresponds to a portion of the second additional pump signal transmitted through the second additional optically non-linear element.

18. The optical logic gate according to claim 16, wherein the phase of the first optical signal corresponds to the phase of the first additional pump signal; and wherein the phase of the second optical signal corresponds to the phase of the second additional pump signal.

19. The optical logic gate according to claim 16, further comprising:
a first connection waveguide passing through the first additional optically non-linear element and connecting it to the optically non-linear element, wherein the first connection waveguide is configured to:
receive the first additional pump signal propagating in a first direction and coupling it into or to the first additional optically non-linear element; and
receive the first optical signal propagating in the first direction and forwarding it to or into the optically non-linear element; and
a second connection waveguide passing through the second additional optically non-linear element and connecting it to the optically non-linear element, wherein the second connection waveguide is configured to:
receive the second additional pump signal propagating in a first direction and coupling it into or to the second additional optically non-linear element; and
receive the second optical signal propagating in the first direction and forwarding it to or into the optically non-linear element.

20. The optical logic gate according to claim 19, wherein:
the first logic input signal propagating in a second direction opposite to the first direction is coupling into or to the first additional optically non-linear element; and
the second logic input signal propagating in a second direction opposite to the first direction is coupling into or to the second additional optically non-linear element.
